(19) United States
(12) Patent Application Publication
(10) Pub. No.: US 2026/0282820 A1
(43) Pub. Date: Sep. 17, 2026

(54) Substrate Processing Apparatus and Method of Operating Substrate Processing Apparatus

(71) Applicant: Tokyo Electron Limited, Tokyo (JP)

(72) Inventor: Hideaki Kubo, Hokkaido (JP)

(21) Appl. No.: 19/552,849

(22) Filed: Feb. 27, 2026

(30) Foreign Application Priority Data
Mar. 14, 2025 (JP) 2025-040857

(51) Int. Cl. H10P 72/30; C23C 16/458; H10P 72/72

(52) U.S. Cl. CPC H10P 72/3304; C23C 16/4586; H10P 72/3302; H10P 72/72

(57) ABSTRACT

There is a substrate processing apparatus includes a processing module, a transfer module, and a controller. The processing module includes a placing table on which a substrate is placed, and a processing chamber that accommodates the placing table. The processing module is configured to perform processing on the substrate placed on the placing table. The transfer module includes a transfer mechanism configured to transfer the substrate onto the placing table. The controller controls the transfer mechanism to place a cover member on the placing table when an idle time period, during which processing on the substrate is not performed in the processing module, exceeds a first time period.

### CROSS-REFERENCE TO RELATED APPLICATIONS

This application claims priority to Japanese Patent Application No. 2025-040857 filed on March 14, 2025, the entire contents of which are incorporated herein by reference.

### TECHNICAL FIELD

The present disclosure relates to a substrate processing apparatus and a method of operating the substrate processing apparatus.

### BACKGROUND

Japanese Laid-open Patent Publication No. 2021-147635 discloses a technique for cleaning an electrostatic chuck in a plasma CVD apparatus.

### SUMMARY

The present disclosure provides a technique for suppressing adhesion of particles onto a placing table.

In accordance with an exemplary embodiment of the present disclosure, there is a substrate processing apparatus that comprises a processing module, a transfer module, and a controller. The processing module includes a placing table on which a substrate is placed, and a processing chamber that accommodates the placing table. The processing module is configured to perform processing on the substrate placed on the placing table. The transfer module includes a transfer mechanism configured to transfer the substrate onto the placing table. The controller controls the transfer mechanism to place a cover member on the placing table when an idle time period, during which processing on the substrate is not performed in the processing module, exceeds a first time period.

### BRIEF DESCRIPTION OF THE DRAWINGS

FIG. 1 is a schematic diagram illustrating a substrate processing apparatus according to an embodiment.

FIG. 2 is a schematic cross-sectional view illustrating an example of a processing module of the substrate processing apparatus of FIG. 1.

FIG. 3 is a flowchart illustrating an example of a method of operating the substrate processing apparatus of FIG. 1.

### DETAILED DESCRIPTION

Hereinafter, non-limiting exemplary embodiments of the present disclosure will be described with reference to the accompanying drawings. Throughout the accompanying drawings, like or corresponding members or components are designated by like or corresponding reference numerals, and redundant description thereof will be omitted.

### Substrate processing apparatus

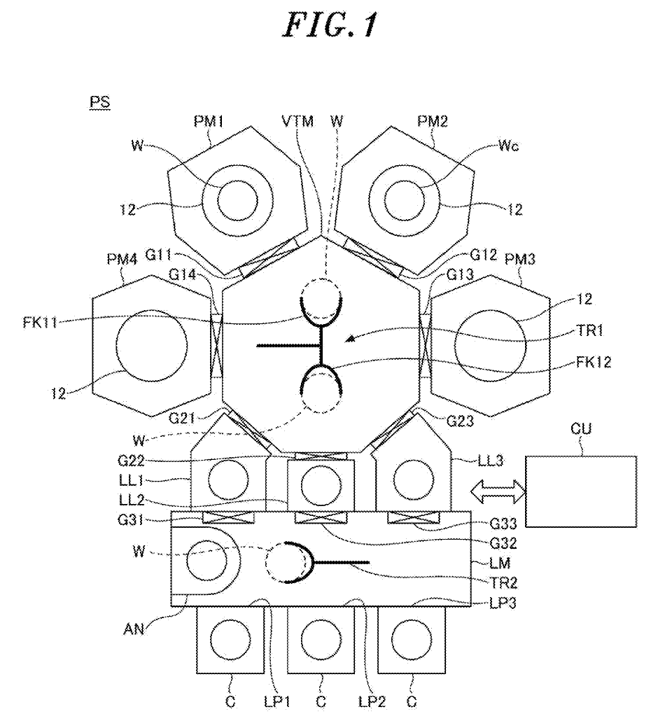

FIG. 1 is a schematic diagram showing a substrate processing apparatus PS according to an embodiment. As shown in FIG. 1, the substrate processing apparatus PS includes processing modules PM1 to PM4, a transfer module VTM, load-lock modules LL1 to LL3, a loader module LM, load ports LP1 to LP3, and an overall controller CU.

The processing modules PM1 to PM4 are connected to the transfer module VTM via gate valves G11 to G14, respectively. The interiors of the processing modules PM1 to PM4 are depressurized to a predetermined vacuum atmosphere. Desired processing is performed on substrates W in the processing modules PM1 to PM4. The substrate W is, e.g., a semiconductor wafer. A placing table 12 is provided in each of the processing modules PM1 to PM4. The placing table 12 is configured to be able to place the substrate W and a cover member Wc thereon. The cover member Wc has the same or substantially the same shape as that of the substrate W. The cover member Wc is, e.g., a dummy substrate. The dummy substrate refers to a substrate that is not a processing target for manufacturing a product. FIG. 1 shows a state in which the substrate W is placed on the placing table 12 of the processing module PM1, the cover member Wc is placed on the placing table 12 of the processing module PM2, and neither the substrate W nor the cover member Wc is placed on the placing tables 12 of the processing modules PM3 and PM4.

The pressure in the transfer module VTM is reduced to a predetermined vacuum atmosphere. A transfer mechanism TR1 is provided in the transfer module VTM. The transfer mechanism TR1 is configured to be able to transfer the substrate W and the cover member Wc under a depressurized state. The transfer mechanism TR1 transfers the substrate W and the cover member Wc to the processing modules PM1 to PM4 and the load-lock modules LL1 to LL3. The transfer mechanism TR1 has, e.g., two independently movable forks FK11 and FK12. Each of the forks FK11 and FK12 is configured to attract and hold the substrate W.

The load-lock modules LL1 to LL3 are connected to the transfer module VTM via gate valves G21 to G23, respectively. The load-lock modules LL1 to LL3 are connected to the loader module LM via gate valves G31 to G33, respectively. A vacuum pump and a leak valve are connected to each of the load-lock modules LL1 to LL3. The vacuum pump and the leak valve allow the inner atmosphere of each of the load-lock modules LL1 to LL3 to be switched between an atmospheric atmosphere and a vacuum atmosphere.

The loader module LM is maintained at an atmospheric atmosphere. For example, downflow of clean air is formed in the loader module LM. An aligner AN is provided in the loader module LM. The aligner AN aligns the substrate W. The aligner AN may be provided outside the loader module LM. The loader module LM is provided with a transfer mechanism TR2. The transfer mechanism TR2 transfers the substrate W and the cover members Wc to the load-lock modules LL1 to LL3, carriers C of the load ports LP1 to LP3, and the aligner AN.

The load ports LP1 to LP3 are provided on a long sidewall of the loader module LM. The carrier C is attached to each of the load ports LP1 to LP3. The carrier C is, e.g., a front opening unified pod (FOUP).

The overall controller/device controller CU is an electronic circuit such as a central processing unit (CPU), a field programmable gate array (FPGA), or an application specific integrated circuit (ASIC). The device controller CU executes instruction codes stored in a memory or is designed as a circuit for special purposes to perform various control operations described herein. For example, the device controller CU controls the operation of the processing modules PM1 to PM4, the operation of the transfer mechanisms TR1 and TR2, the opening and closing of the gate valves G11 to G14, G21 to G23, and G31 to G33, and the switching of atmospheres in the load-lock modules LL1 to LL3.

Next, an example of the operation performed when predetermined processing is performed on the substrate W in the processing module PM1 of the substrate processing apparatus PS will be described. The operation performed when predetermined processing is performed on the substrate W in the processing modules PM2 to PM4 may be similar to the operation performed when predetermined processing is performed on the substrate W in the processing module PM1. The operation of the substrate processing apparatus PS is performed under the control of the overall controller CU.

First, the carrier C containing multiple substrates W is attached to the load port LP1.

Next, the transfer mechanism TR2 transfers the substrate W contained in the carrier C to the aligner AN. Then, the aligner AN aligns the substrate W. Next, the overall controller CU switches the gate valve G31 from a closed state to an open state. Next, the transfer mechanism TR2 receives the substrate W from the aligner AN, and transfers the substrate W to the load-lock module LL1 maintained at an atmospheric atmosphere. Next, the overall controller CU switches the gate valve G31 from an open state to a closed state. Next, the overall controller CU switches the inner atmosphere of the load-lock module LL1 from an atmospheric atmosphere to a vacuum atmosphere.

Next, the overall controller CU switches the gate valves G11 and G21 from a closed state to an open state. Next, the transfer mechanism TR1 receives the substrate W from the load-lock module LL1, transfers the substrate W into the processing chamber 11 of the processing module PM1, and places the substrate W on the placing table 12. Next, the overall controller CU switches the gate valves G11 and G21 from an open state to a closed state. The placing table 12 attracts and holds the substrate W placed thereon.

Next, the processing module PM1 performs predetermined processing on the substrate W placed on the placing table 12. The predetermined processing is, e.g., processing for forming a titanium film on the substrate W. When the predetermined processing is completed, the placing table 12 releases the attraction and holding of the substrate W.

Next, the overall controller CU switches the gate valves G11 and G23 from a closed state to an open state. Next, the transfer mechanism TR1 receives the substrate from the processing module PM1 and transfers the substrate to the load-lock module LL3 maintained at a vacuum atmosphere. Next, the overall controller CU switches the gate valves G11 and G23 from an open state to a closed state. Next, the overall controller CU switches the inner atmosphere of the load-lock module LL3 from a vacuum atmosphere to an atmospheric atmosphere.

Next, the overall controller CU switches the gate valve G33 from a closed state to an open state. Next, the transfer mechanism TR2 receives the substrate W from the load-lock module LL3, transfers the substrate W to the carrier C attached to the load port LP3, and places the substrate W in the carrier C. Accordingly, the processing for one substrate W is completed.

In the above-described operation of the substrate processing apparatus PS, in the case of loading the substrate W into the processing module PM1, the substrate W is transferred from the loader module LM to the transfer module VTM via the load-lock module LL1. However, the loading route of the substrate W is not limited thereto. For example, the load-lock modules LL2 and LL3 may be used instead of the load-lock module LL1. In the case of unloading the substrate W, the substrate W is transferred from the transfer module VTM to the loader module LM via the load-lock module LL3. However, the unloading route of the substrate W is not limited thereto. For example, the load-lock modules LL1 and LL2 may be used instead of the load-lock module LL3.

### Processing module

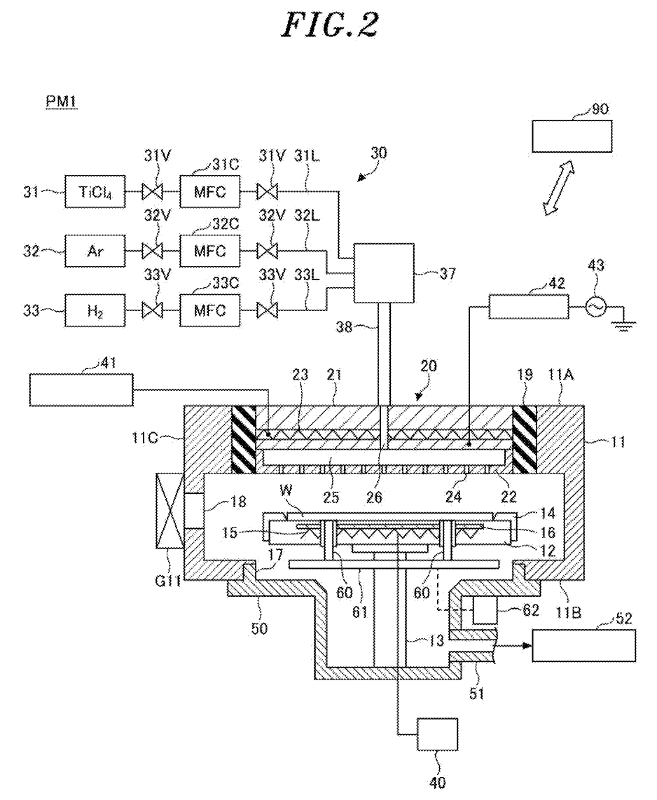

FIG. 2 is a schematic cross-sectional view showing an example of the processing module PM1 of the substrate processing apparatus PS shown in FIG. 1. Hereinafter, the case where the processing module PM1 is a film forming apparatus that forms a titanium (Ti) film on the substrate W by plasma-enhanced chemical vapor deposition (PECVD) will be described as an example. However, the processing module PM1 may also be an etching apparatus. The processing modules PM2 to PM4 may also have the same configuration as that of the processing module PM1.

The processing module PM1 includes a processing chamber 11. The processing chamber 11 is configured to be airtight and has a substantially cylindrical shape. The placing table 12 is provided in the processing chamber 11. The placing table 12 horizontally attracts and holds the substrate W. The placing table 12 may horizontally attract and hold the cover member Wc instead of the substrate W. The placing table 12 is supported by a substantially cylindrical support member 13 provided at the center of the bottom portion. The placing table 12 is made of a conductive ceramic such as aluminum nitride (AlN) or the like.

A guide ring 14 is provided around the outer edge of the placing table 12. The guide ring 14 guides the substrate W to be positioned at the center of the placing table 12.

A heater 15 and a lower electrode 16 are provided in the placing table 12. The heater 15 receives a power from a heater power supply 40 to heat the substrate W to a predetermined temperature. The lower electrode 16 is electrically connected to a chuck power supply (not shown). The chuck power supply is, e.g., a DC power supply. The chuck power supply may be an AC power supply. When a voltage is applied from the chuck power supply to the lower electrode 16, the substrate W is electrostatically attracted to the placing table 12 by Coulomb force. In other words, the placing table 12 and the lower electrode 16 function as an electrostatic chuck.

A shower head 20 is attached to a ceiling wall 11A of the processing chamber 11 via an insulating member 19. The shower head 20 includes an upper base member 21 and a shower plate 22 attached to the bottom portion of the base member 21.

The heater 23 is provided in the base member 21. The heater 23 receives a power from a heater power supply 41 to heat the shower head 20 to a predetermined temperature.

The shower plate 22 has multiple injection holes 24. Each of the injection holes 24 inject a processing gas into the processing chamber 11. Each of the injection holes 24 communicate with a gas diffusion space 25 formed between the base member 21 and the shower plate 22. A gas inlet port 26 is provided at the center of the base member 21. The gas inlet port 26 supplies a processing gas to the gas diffusion space 25. The gas inlet port 26 is connected to a mixed gas supply line 38 of a gas supply part 30, which will be described later.

The gas supply part 30 includes a TiCl₄ gas supply source 31 for supplying TiCl₄ gas that is a Ti compound gas, an Ar gas supply source 32 for supplying Ar gas, and an H₂ gas supply source 33 for supplying H₂ gas that is a reducing gas.

A TiCl₄ gas supply line 31L is connected to the TiCl₄ gas supply source 31. An Ar gas supply line 32L is connected to the Ar gas supply source 32. An H₂ gas supply line 33L is connected to the H₂ gas supply source 33. The gas supply lines 31L to 33L are provided with two valves 31V and 33V with flow rate controllers 31C to 33C interposed therebetween, respectively. The flow rate controllers 31C to 33C are, e.g., mass flow controllers (MFC).

A gas mixing part 37 mixes TiCl₄ gas, Ar gas, and H₂ gas and supplies the mixed gas to the shower head 20. The gas inlet side of the gas mixing part 37 is connected to the TiCl₄ gas supply source 31, the Ar gas supply source 32, and the H₂ gas supply source 33 via the gas supply lines 31L to 33L. The gas outlet side of the gas mixing part 37 is connected to the shower head 20 via the mixed gas supply line 38.

In the case of forming a titanium film on the substrate W, one or more gases selected from TiCl₄ gas, Ar gas, and H₂ gas are introduced into the processing chamber 11 through the gas inlet port 26, the gas diffusion space 25, and the multiple injection holes 24. In other words, the processing module PM1 is configured as a pre-mix type in which multiple processing gases are mixed in advance and supplied into the processing chamber 11. However, the processing module PM1 may be configured as a post-mix type in which multiple processing gases are supplied independently into the processing chamber 11.

A radio frequency (RF) power supply 43 is connected to the shower head 20 via a matching device 42. By supplying an RF power from the RF power supply 43 to the shower head 20 while the processing gas is being supplied to the processing chamber 11, plasma is generated between the shower head 20 and the lower electrode 16. In this manner, the shower head 20 functions as an upper electrode located to face the lower electrode 16. The frequency of the RF power is, e.g., 450 kHz. The frequency of the RF power is not limited to 450 kHz, and may be 2 MHz, 13.56 MHz, 27 MHz, 60 MHz, 100 MHz, or the like.

A circular opening 17 is formed at the center of a bottom wall 11B of the processing chamber 11. An exhaust chamber 50 protruding downward is provided at the bottom wall 11B to cover the opening 17. An exhaust line 51 is connected to the side surface of the exhaust chamber 50. An exhaust device 52 is connected to the exhaust line 51. The exhaust device 52 reduces the pressure in the processing chamber 11 to a predetermined vacuum pressure. The exhaust device 52 includes, e.g., a vacuum pump.

The placing table 12 is provided with multiple (e.g., three) lift pins 60 that can protrude from and retracted into the surface of the placing table 12 to support and raise and lower the substrate W. The lift pins 60 are fixed to a support plate 61. The lift pins 60 are raised and lowered via the support plate 61 by a driving mechanism 62, such as an air cylinder. A sidewall 11C of the processing chamber 11 is provided with a loading/unloading port 18 for loading and unloading the substrate W, and a gate valve G11 for opening/closing the loading/unloading port 18.

The lift pins 60 raise and lower the substrate W when the substrate W is loaded into and unloaded from the processing chamber 11. Specifically, in the case of loading the substrate W into the processing chamber 11, first, the lift pins 60 are raised, and the substrate W is loaded from the loading/unloading port 18 by a transfer arm (not shown) and placed on the lift pins 60. Then, the lift pins 60 are lowered to place the substrate W on the placing table 12. In the case of unloading the substrate W from the processing chamber 11, first, the lift pins 60 are raised to lift the substrate W. Then, the substrate W is received by the transfer arm (not shown) and unloaded from the loading/unloading port 18.

The processing module PM1 includes a module controller 90. The module controller 90 is an electronic circuit such as a central processing unit (CPU), a field programmable gate array (FPGA), or an application specific integrated circuit (ASIC). The module controller 90 executes instruction codes stored in a memory or is designed as a circuit for special purposes to perform various control operations described herein.

### Operating method of substrate processing apparatus

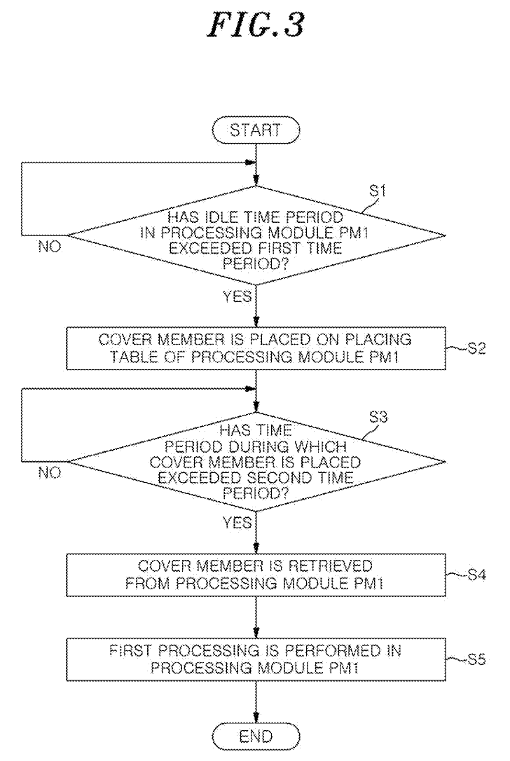

FIG. 3 is a flowchart showing an example of an operating method of a substrate processing apparatus PS of FIG. 1. Hereinafter, an operating method of the processing module PM1 will be described as an example. However, the operating methods of the processing modules PM2 to PM4 may be the same as the operating method of the processing module PM1.

The operating method of the substrate processing apparatus PS shown in FIG. 3 is performed under the control of the device controller CU. The operating method of the substrate processing apparatus PS shown in FIG. 3 is executed after the processing of the substrate W in the processing module PM1 is performed, for example. The operating method of the substrate processing apparatus PS shown in FIG. 3 may also be executed after first processing to be described below is performed in the processing module PM1.

In step S1, the device controller CU determines whether or not an idle time period, during which the substrate W is not processed in the processing module PM1, exceeds a first time period. If the idle time period does not exceed the first time period (NO in step S1), step S1 is executed again. If the idle time period exceeds the first time period (YES in step S1), the processing proceeds to step S2.

In step S2, the transfer mechanism TR1 transfers the cover member Wc into the processing chamber 11 of the processing module PM1 and places the cover member Wc on the placing table 12. Accordingly, when the processing module PM1 is in an idle state, the upper surface of the placing table 12 is protected by the cover member Wc, thereby reducing particle adhesion to the placing table 12. Further, it is possible to prevent a film from being formed on the upper surface of the placing table 12 due to the processing gas remaining in the processing chamber 11. As a result, the attractive force of the placing table 12 as an electrostatic chuck can be maintained. The placing table 12 may attract and hold the cover member Wc placed thereon.

In step S3, the device controller CU determines whether or not a time period, during which the cover member Wc is placed on the placing table 12 of the processing module PM1, exceeds a second time period. If the time period, during which the cover member Wc is placed, does not exceed the second time period (NO in step S3), step S3 is executed again. If the time period, during which the cover member Wc is placed, exceeds the second time period (YES in step S3), the processing proceeds to step S4.

In step S4, the transfer mechanism TR1 receives the cover member Wc placed on the placing table 12 of the processing module PM1, and retrieves the cover member Wc from the processing chamber 11 of the processing module PM1. The retrieved cover member Wc is stored in, e.g., the carrier C.

In step S5, the device controller CU executes control to perform the first processing in the processing module PM1 in a state where the cover member Wc is not placed on the placing table 12 and, then, the processing is terminated. The first processing is, e.g., a leak measurement or a conditioning process.

The leak measurement is performed to detect the leakage in the processing chamber 11. The leak measurement method includes a pressure test, a vacuum test, or the like. For example, in the leak measurement, the processing chamber 11 is evacuated by the exhaust device 52, the exhaust operation is stopped, and the temporal changes in pressure in the processing chamber 11 are measured to check for leakage into the processing chamber 11. In this operating method, the leak measurement is performed in a state where the substrate W or the cover member Wc is not located in the processing chamber 11. Accordingly, the volume inside the processing chamber 11 can be accurately determined, thereby improving the measurement accuracy. Since there is no influence from outgassing from the substrate W or the cover member Wc, the measurement accuracy is improved. In addition, it is possible to prevent the generation of particles caused by the displacement of the substrate W and the cover member Wc from the placing table 12.

The conditioning process is performed to stabilize a state inside the processing chamber 11. The conditioning process includes, e.g., a cooling step, a cleaning step, and a pre-coating step. In the cooling step, the temperature of the placing table 12 is lowered to a temperature suitable for performing the cleaning step. In the cleaning step, a cleaning gas is supplied into the processing chamber 11 to remove a film that has been adhered to the inside of the processing chamber 11 by the processing of the substrate W. For example, if the film is a titanium film or a titanium nitride film, ClF₃ gas is used as the cleaning gas. In the pre-coating step, a pre-coating gas is supplied into the processing chamber 11 to coat the inside of the processing chamber 11 with a pre-coating film. The pre-coating film stabilizes the internal state of the processing chamber 11. For example, when a titanium film or a titanium nitride film is formed by the processing of the substrate W, TiCl₄ gas or NH₃ gas is used as the pre-coating gas. In this operating method, the cooling step and the cleaning step are performed in a state where the substrate W and the cover member Wc are not provided in the processing chamber 11. Accordingly, it is possible to prevent the generation of particles caused by the displacement of the substrate W and the cover member Wc from the placing table 12 during the cooling step and the cleaning step. In this operating method, the cleaning step is performed in a state where the upper surface of the placing table 12 is not covered by the substrate W and the cover member Wc. Hence, the particles adhered to the upper surface of the placing table 12 can be removed by cleaning. AlN-based electrostatic chucks are typically pre-treated by fluorinating the surfaces thereof to attract and hold the substrate W even at a low voltage. However, the fluorine components on the surface of the electrostatic chuck may decrease after repeated processing on the substrate W. In this operating method, the cleaning step is performed in a state where the upper surface of the placing table 12 is not covered by the substrate W and the cover member Wc. Therefore, the fluorine components can be replenished on the surface of the electrostatic chuck. In this operating method, the pre-coating step may be performed in a state where the cover member Wc is placed on the placing table 12. In this case, after the cleaning step is completed, the transfer mechanism TR1 transfers the cover member Wc into the processing chamber 11 of the processing module PM1, places the cover member Wc on the placing table 12, and then executes the pre-coating step. After the pre-coating step is completed, the transfer mechanism TR1 receives the cover member Wc placed on the placing table 12 of the processing module PM1, and retrieves the cover member Wc from the processing chamber 11 of the processing module PM1.

As described above, according to the embodiment, the device controller CU controls the transfer mechanism TR1 to place the cover member Wc on the placing table 12 when the idle time period in which no processing is performed on the substrate W in the processing module PM1 exceeds the first time period. In this case, if the processing module PM1 is in an idle state, the upper surface of the placing table 12 is protected by the cover member Wc, thereby reducing particle adhesion to the placing table 12. Further, it is possible to prevent a film from being deposited on the upper surface of the placing table 12 by the processing gas remaining in the processing chamber 11. As a result, the attractive force of the placing table 12 as an electrostatic chuck can be maintained.

Further, according to the embodiment, when the time period in which the cover member Wc is placed on the placing table 12 of the processing module PM1 exceeds the second time period, the device controller CU retrieves the cover member Wc from the processing module PM1 and then performs the first processing. The inner atmosphere of the processing chamber 11 deteriorates over time, but the inner atmosphere of the processing chamber 11 can be automatically refreshed by selecting a conditioning process as the first processing.

In the above embodiment, the cover member Wc is retrieved from the processing module PM1 when the time period in which the cover member Wc is placed on the placing table 12 of the processing module PM1 exceeds the second time period. However, the present disclosure is not limited thereto. For example, the device controller CU may execute control to retrieve the cover member Wc from the processing module PM1 at a pre-specified date and time. In this case, the first processing (e.g., leak measurement) can be performed periodically at the pre-specified date and time.

It should be noted that the above-described embodiments are illustrative in all respects and are not restrictive. The above-described embodiments may be omitted, replaced, or changed in various forms without departing from the scope of the appended claims and the gist thereof.

1. A substrate processing apparatus comprising:
a processing module including a placing table on which a substrate is placed, and a processing chamber that accommodates the placing table, the processing module being configured to perform processing on the substrate placed on the placing table;
a transfer module including a transfer mechanism configured to transfer the substrate onto the placing table; and
a controller;
wherein the controller controls the transfer mechanism to place a cover member on the placing table when an idle time period, during which processing on the substrate is not performed in the processing module, exceeds a first time period.

2. The substrate processing apparatus of claim 1, wherein the placing table includes an electrostatic chuck that attracts and holds the substrate.

3. The substrate processing apparatus of claim 1, wherein the controller controls the transfer mechanism to unload the cover member from the placing table when a time period, during which the cover member is placed on the placing table, exceeds a second time period, and controls the processing module to perform first processing in a state where the cover member is not placed on the placing table.

4. The substrate processing apparatus of claim 3, wherein the controller controls the transfer mechanism to place the cover member on the placing table when an idle time period, during the processing on the substrate is not performed in the processing module, exceeds the first time period after completion of the first processing.

5. The substrate processing apparatus of claim 3, wherein the first processing is leak measurement for detecting leakage in the processing chamber.

6. The substrate processing apparatus of claim 3, wherein the first processing is a conditioning process for stabilizing a state inside the processing chamber.

7. A method of operating a substrate processing apparatus including a processing module and a transfer module,
wherein the processing module includes a placing table on which a substrate is placed, and a processing chamber that accommodates the placing table, and is configured to perform processing on the substrate placed on the placing table,
the transfer module includes a transfer mechanism configured to transfer the substrate onto the placing table, and
when an idle time period, during which processing on the substrate is not performed in the processing module, exceeds a first time period, the transfer mechanism places a cover member on the placing table.

8. The substrate processing apparatus of claim 1, wherein the cover member is stored in a carrier attached to a load port during a period in which the cover member is not disposed in the processing module.

9. The substrate processing apparatus of claim 2, wherein the electrostatic chuck comprises a conductive ceramic body and a lower electrode embedded in the conductive ceramic body.

10. The substrate processing apparatus of claim 1, wherein the placing table comprises a heater embedded therein to heat the substrate or the cover member placed thereon.

11. The substrate processing apparatus of claim 1, wherein the processing module further comprises a shower head disposed to face the placing table and having a gas diffusion space and a plurality of gas injection holes.

12. The substrate processing apparatus of claim 1, wherein a radio frequency (RF) power supply is connected to the shower head via a matching device, and plasma is generated in the processing chamber by RF power supplied from the RF power supply.

13. The substrate processing apparatus of claim 2, wherein the controller is further configured to operate the electrostatic chuck to electrostatically attract and hold the cover member during the idle time period.

14. The substrate processing apparatus of claim 1, wherein the controller is configured to record a number of uses of the cover member and instruct replacement when the number of uses exceeds a predetermined value.

15. The substrate processing apparatus of claim 3, wherein the second time period is set based on a time required for a temperature of the processing chamber to become equal to or lower than a predetermined temperature.

16. The method of claim 7, further comprising: after unloading the cover member, evacuating the processing chamber to a predetermined vacuum pressure and determining a leak by measuring a pressure change while the evacuation is suspended.

17. The method of claim 7, further comprising: purging an interior of the processing chamber with an inert gas before placing the cover member on the placing table.

18. The method of claim 7, wherein the first time period is varied based on a number of the substrates processed in the processing module.

19. The method of claim 7, further comprising: storing the cover member in a carrier attached to a load port during a period in which the cover member is not placed on the placing table.
